(19) United States
(12) Patent Application Publication
(10) Pub. No.: US 2026/0247996 A1
(43) Pub. Date: Aug. 20, 2026

(54) PACKAGE AND METHOD OF FORMING THE SAME

(71) Applicant: Taiwan Semiconductor Manufacturing Co., Ltd., Hsinchu (TW)

(72) Inventors: Kuo-Chiang Ting, Hsinchu (TW); Sung-Feng Yeh, Taipei City (TW); Ta Hao Sung, Hsinchu (TW); Cheng-Chia Wang, Taichung City (TW); Hao-Cheng Lin, Hsinchu (TW); Hao-Wen Ko, Zhubei City (TW)

(21) Appl. No.: 19/238,779

(22) Filed: Jun. 16, 2025

Related U.S. Application Data
(60) Provisional application No. 63/760,453, filed on Feb. 19, 2025.

(51) Int. Cl. H01L 23/538; H01L 21/56; H01L 23/00; H01L 23/31; H01L 25/04

(52) U.S. Cl. CPC H10W 70/611; H10W 70/635; H10W 74/019; H10W 74/111; H10W 90/00; H10W 90/734

(57) ABSTRACT

A method includes forming a base bond structure, bonding a first device die to a first side of the base bond structure, encapsulating the first device die in a first gap-fill region, and bonding a second device die to a second side of the base bond structure. The first device die is electrically coupled to the second device die through a first conductive feature in the base bond structure. The method further includes encapsulating the second device die in a second gap-fill region, thinning a semiconductor substrate in the second device die to reveal a through-via in the semiconductor substrate, and forming a second conductive feature. The second conductive feature is electrically coupled to the first device die through the through-via in the semiconductor substrate of the second device die. An electrical connector is formed and is connected to the second conductive feature.

### PRIORITY CLAIM AND CROSS-REFERENCE

This application claims the benefit of the following provisionally filed U.S. patent application Ser. No. 63/760,453, filed on Feb. 19, 2025, and entitled “System on Integrated Chips (SoIC) Scheme for Node Stacking,” which application is hereby incorporated herein by reference.

### BACKGROUND

The packages of integrated circuits are becoming increasing complex, with more device dies integrated in the same package to achieve more functions. For example, a plurality of device dies such as processors and memory cubes may be bonded and integrated together. The package can include device dies formed using different technologies and have different functions, thus forming a system. This may save manufacturing cost and optimize device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-11 illustrate the cross-sectional views of intermediate stages in the formation of a package in accordance with some embodiments.

FIGS. 12-21 illustrate the cross-sectional views of intermediate stages in the formation of a package in accordance with some embodiments.

FIG. 22 illustrates a metal pad in a base bond structure in accordance with some embodiments.

FIG. 23 illustrates a single damascene redistribution line in a base bond structure in accordance with some embodiments.

FIG. 24 illustrates a dual damascene redistribution line in a base bond structure in accordance with some embodiments.

FIG. 25 illustrates a capacitor in a base bond structure in accordance with some embodiments.

FIG. 26 illustrates the structure of bond films in a device die in accordance with some embodiments.

FIG. 27 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, a base bond structure is formed. Discrete dies are bonded to the opposite sides of the base bond structure, and are electrically interconnected through conductive features in the base bond structure. Since the methods of forming packages in accordance with the embodiments of the present disclosure enables the using of known-good-dies, the manufacturing yield is improved.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

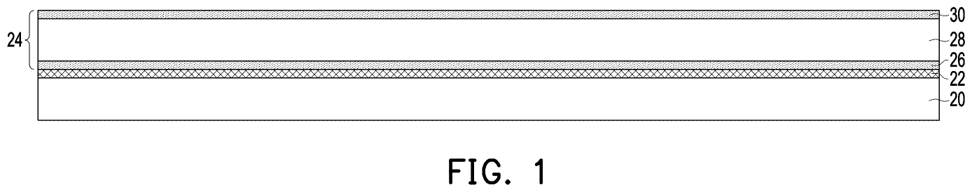

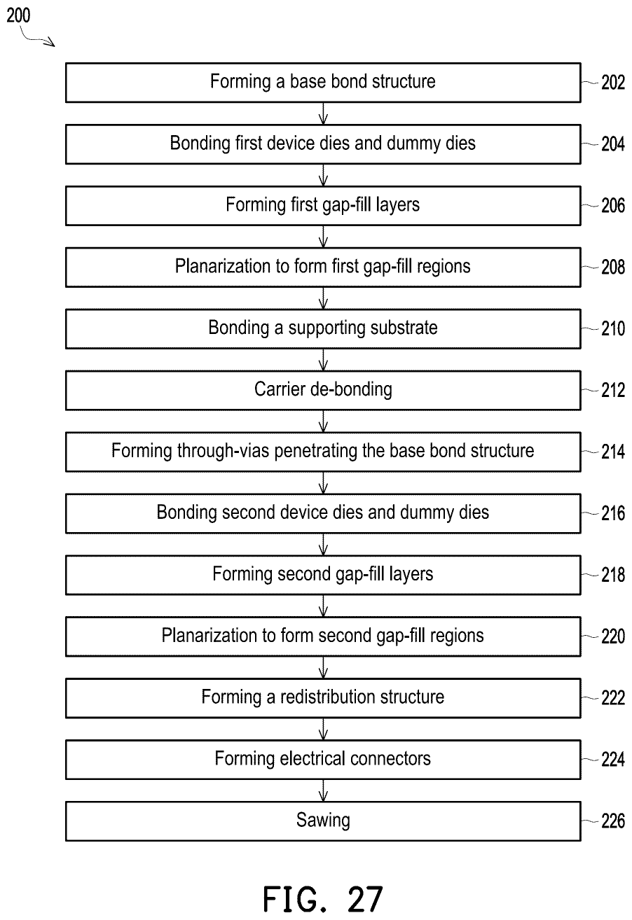

FIGS. 1 through 11 illustrate the cross-sectional views of intermediate stages in the formation of a package in accordance with some embodiments of the present disclosure. The corresponding processes are also reflected schematically in the process flow shown in FIG. 27.

FIG. 1 illustrates the formation of base bond structure 24. The respective process is illustrated as process 202 in the process flow 200 as shown in FIG. 27. Carrier 20 is provided, with release film 22 being coated on carrier 20. Carrier 20 may be a glass carrier, a silicon wafer, an organic carrier, or the like. Release film 22 may be formed of a polymer-based material and/or an epoxy-based thermal-release material, such as a Light-to-Heat-Conversion (LTHC) material.

Base bond structure 24 is formed over release film 22. Base bond structure 24 may include a plurality of dielectric layers, and thus may be referred to as a composite base bond structure. For example, as illustrated in FIG. 1, base bond structure 24 includes dielectric layers 26, 28, and 30. Each of dielectric layers 26, 28, and 30 may be formed of or comprise AlO, SiO, SiN, SiCN, TiO, AlN, BN, SiON, SiCO, SiOCN, or the like, or combinations thereof. Dielectric layers 26, 28, and 30 may be deposited over release film 22 layer-by-layer, or pre-formed and adhered to release film 22.

In accordance with some embodiments, either one or both of dielectric layers 26 and 30 may be an enhanced bond layer. Throughout the description, when a bond layer is referred to as an “enhance bond layer” or an “enhanced layer,” it indicates that the bond layer has a greater bond strength when bonding to a silicon-containing dielectric layer than the bond strength between two bonded silicon-containing dielectric layers. The silicon-containing dielectric layer(s) may be any of the material comprising SiO, SiN, SiC, or combinations thereof. In accordance with some embodiments, the enhanced bond layer comprises AlO, which may be Al₂O₃. Silicon-containing dielectric materials such as SiO, SiN, SiC, SiOC, SiON, SiOCN, and the like are thus non-enhanced bond layers.

In accordance with alternative embodiment, base bond structure 24 is a dual-layer structure formed of two dielectric layers that comprise different materials. Either the top layer or the bottom layer, or both, or neither of the two layers may be the enhance bond layer in accordance with these embodiments. In accordance with yet alternative embodiment, base bond structure 24 is a single-layer structure that is formed of a single homogenous dielectric layer. The single homogenous dielectric may be an enhance bond layer or a non-enhanced bond layer.

In accordance with some embodiments, an entirety of the base bond structure 24 has no conductive features such as metal features therein. Accordingly, the corresponding dielectric layers 26, 28, and/or 30 are planar layers, with each being formed of a homogeneous material.

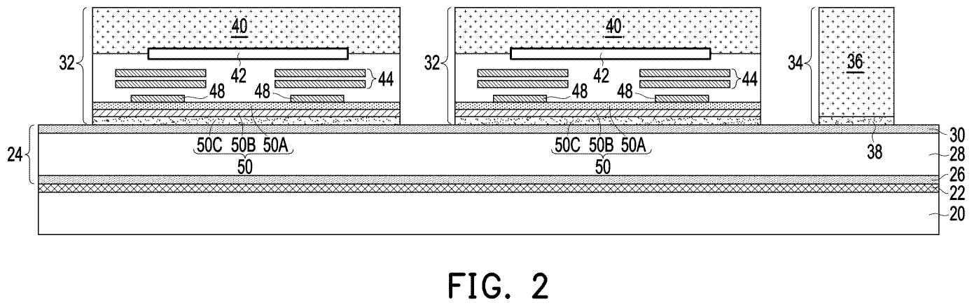

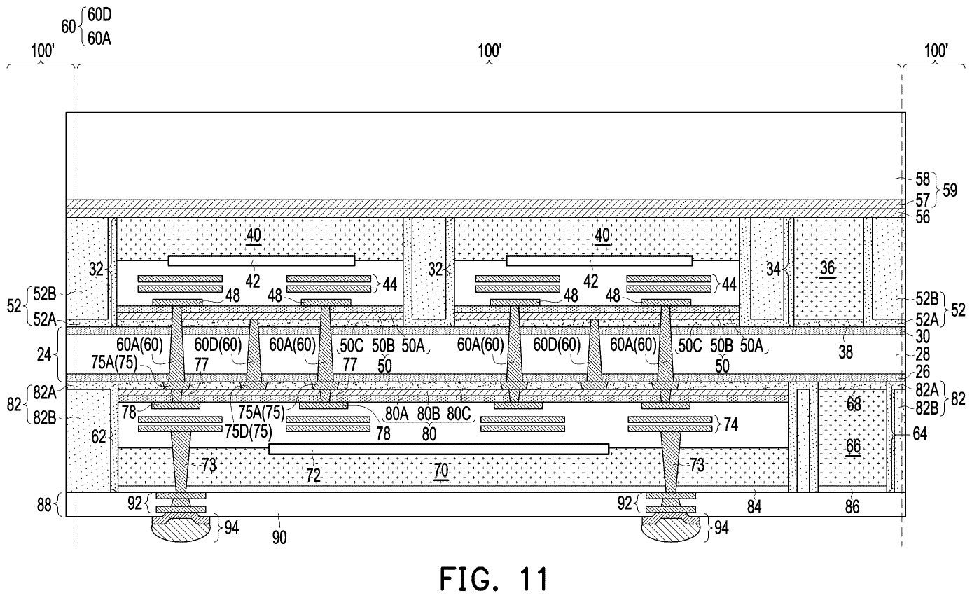

Referring to FIG. 2, device dies 32 and dummy dies 34 are bonded to base bond structure 24. The respective process is illustrated as process 204 in the process flow 200 as shown in FIG. 27. Although two device dies 32 are illustrated as an example, the illustrate device dies 32 represent a plurality of groups of device dies 32, with each group being in one of the final package 100′ as shown in FIG. 11. In accordance with some embodiments, each of device dies 32 may be a logic die, which may be a Central Processing Unit (CPU) die, a microcontroller (MCU) die, an input-output (IO) die, a BaseBand die, or the like. Device dies 32 may also include memory dies.

Device dies 32 may include semiconductor substrates 40, integrated circuit devices 42, interconnect structures 44, and bond layers 50. Semiconductor substrates 40 may be silicon substrates. Integrated circuit devices 42 may comprise active devices (such as transistors, diodes, and/or the like) and passive devices (such as capacitors, resistors, and/or the like). Interconnect structures 44 are used for connecting to the active devices and passive devices in device dies 32. Metal pads 48 are formed to electrically connect to interconnect structure 44.

In accordance with some embodiments, dielectric layers 50 (also referred to as bond films) include dielectric layers 50A, 50B, and 50C. The neighboring layers of dielectric layers 50A, 50B, and 50C are formed of different martials. FIG. 26 schematically illustrates possible structures of dielectric layers 50. In accordance with some embodiments, dielectric layer 50A comprises an oxide such as silicon oxide, while other elements such as C and/or N may or may not be added. Dielectric layer 50B may comprise a nitride such as silicon nitride, while other elements such as C and O may or may not be added.

Dielectric layers 50 may or may not include dielectric layer 50C. In accordance with some embodiments, dielectric layer 50C, when formed, is the surface layer of the respective device die 32. In accordance with these embodiments, dielectric layer 50C may be an enhanced bond layer, or may be formed of a silicon-containing dielectric material. When dielectric layer 50C is formed and is an enhanced bond layer, dielectric layer 50D may be, or may not be formed between dielectric layers 50B and 50C. In accordance with some embodiments, dielectric layer 50D may comprise an oxide such as silicon oxide. Dielectric layers 50C and 50D are illustrated as being dashed to indicate that each of dielectric layers 50C and 50D may or may not be a part of dielectric layer 50.

Referring back to FIG. 2, in accordance with some embodiments, the bonding of device dies 32 to base bond structure 24 may be through fusion bonding, with O-Si-O bonds and/or Si-O-Si bonds being formed to join the surface layer (such as dielectric layer 50C) to the bond base structure 24. Other types of bonds such as metal-oxide-metal bonds may be formed to improve the bonding strength, for example, when device die 32 comprises an enhanced bond layer 50C that is bonded to the enhanced bond layer 30 in the bond base structure 24.

In accordance with some embodiments, a plurality of dummy dies 34 are attached to bond base structure 24. A dummy die 34 may include dummy region 36 and bond layer 38. Dummy region 36 may comprise silicon. Bond layer 38 may include a silicon-containing dielectric material, which may be a non-enhanced bond layer selected from SiO, SiC, SiN, SiON, SiOC, SiCN, SiOCN, or the like, or combinations thereof. Alternatively, bond layer 38 may be an enhance bond layer, for example, comprising Al₂O₃. The bonding may be performed by bonding bond layer 38 to bond layer 30, and the bonding may be similar to the bonding of device dies 32 to bond base structure 24 as discussed above.

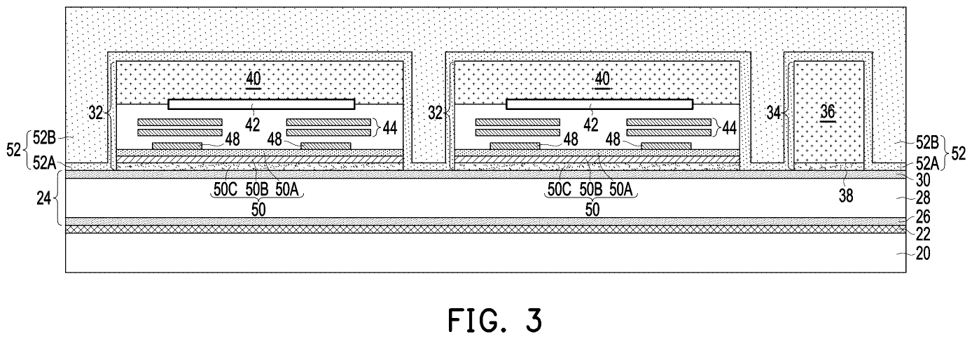

FIG. 3 illustrates the formation of gap-fill layers comprising adhesion layer 52A and dielectric layer 52B, which are individually and collectively referred to as dielectric layers 52. The respective process is illustrated as process 206 in the process flow 200 as shown in FIG. 27. Adhesion layer 52A may be formed of a dielectric material that has a good adhesion to device dies 32 and dummy dies 34.

In accordance with some embodiments, adhesion layer 52A is formed of or comprises a nitride-containing material such as silicon nitride. Adhesion layer 52A may be a conformal layer, with the horizontal thickness of horizontal portions and the vertical thickness of the vertical portions being substantially equal to each other, for example, with a variation smaller than about 20 percent, or smaller than about 10 percent. The deposition may be performed through a conformal deposition method such as ALD, CVD, or the like.

Dielectric layer 52B may be formed of a material different from the material of adhesion layer 52A. In accordance with some embodiments of the present disclosure, dielectric layer 52B is formed of silicon oxide, while other dielectric materials such as silicon carbide, silicon oxynitride, silicon oxy-carbo-nitride, phosphosilicate glass (PSG), borosilicate glass (BSG), boron-doped phosphosilicate glass (BPSG), or the like may also be used.

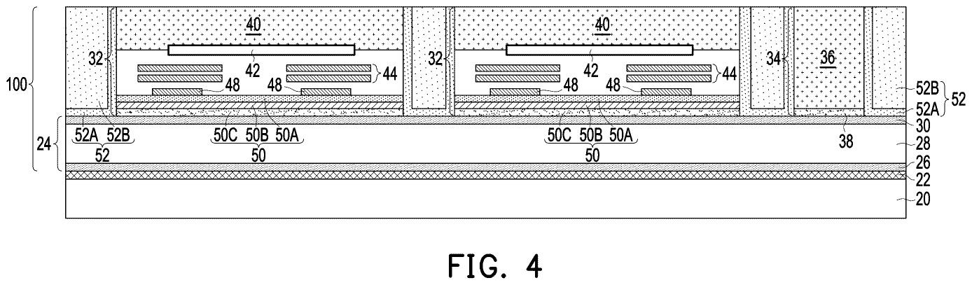

Referring to FIG. 4, a planarization process such as a Chemical Mechanical Polish (CMP) process or a mechanical grinding process is performed to remove excess portions of dielectric layers 52A and 52B, so that device dies 32 and dummy dies 34 are exposed. The remaining portions of dielectric layers 52A and 52B are individually and collectively referred to as gap-fill regions 52 or dielectric regions 52 hereinafter. The respective process is illustrated as process 208 in the process flow 200 as shown in FIG. 27. In subsequent discussion, the structure over release film 22 is referred to as reconstructed wafer 100.

In accordance with some embodiments, after the planarization process, dummy dies 34 are exposed. In accordance with alternative embodiments, after the planarization process, dummy dies 34 are buried in gap-fill regions 52, and a portion of dielectric layer 52A and a portion of dielectric layer 52B may be left overlapping a dummy die 34.

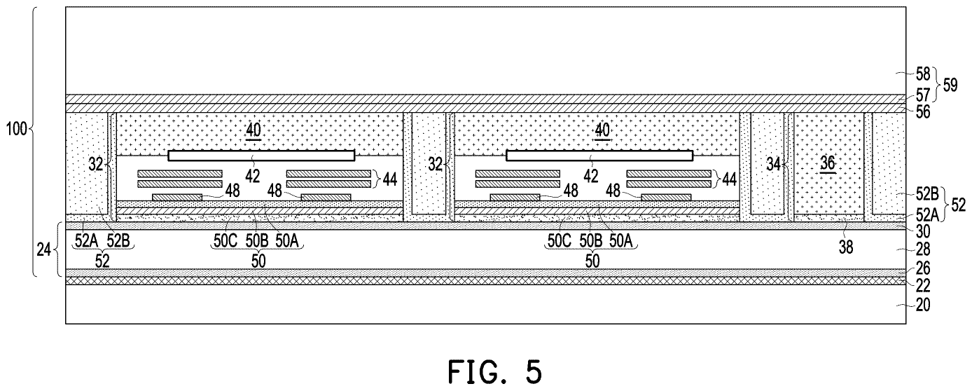

Referring to FIG. 5, bond layer 56 is deposited over the semiconductor substrates 40 of device dies 32, and over dummy dies 34 and gap-fill regions 52. Bond layer 56 may also be formed of or comprise a silicon-containing dielectric material, which may be selected from SiO, SiC, SiN, SiON, SiOC, SiCN, SiOCN, or the like, or combinations thereof. A planarization process may then be performed to level the top surface of bond layer 56.

In a subsequent process, as also shown in FIG. 5, supporting substrate 59 is bonded to the underlying structure to expand reconstructed wafer 100. The respective process is illustrated as process 210 in the process flow 200 as shown in FIG. 27. Supporting substrate 59 includes bond layer 57 and dummy region 58. The bond layer 57 may be formed of a silicon-containing dielectric material selected from the same group of candidate materials of bond layer 57. Bond layer 57 may also be an enhanced bond layer, which may comprise, for example, Al₂O₃. The materials of bond layers 56 and 57 may be the same as each other or different from each other.

In accordance with some embodiments, the entire dummy region 58 is formed of a homogeneous material, with no other materials and structures therein. Dummy region 58 may be formed of silicon, while a metal-containing material such as a metal (for example, Cu, Au, Ag, or the like), or a material such as SiC, BeO, SiCN, or the like may also be used.

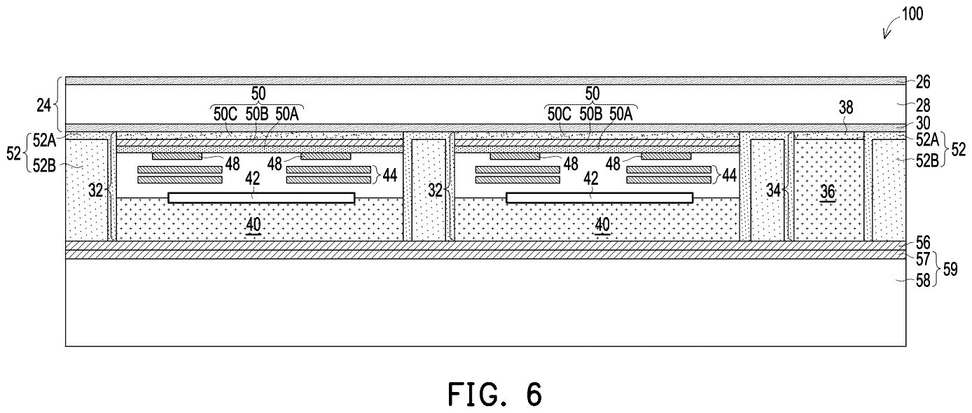

Carrier 20 is then de-bonded from reconstructed wafer 100, and the resulting structure is illustrated in FIG. 6, which shows an upside-down structure than what is shown in FIG. 5. The respective process is illustrated as process 212 in the process flow 200 as shown in FIG. 27. In accordance with some embodiments in which carrier 20 is a glass carrier, reconstructed wafer 100 may be de-bonded from carrier 20 by projecting a laser beam through carrier 20 and onto release film 22, which may be a LTHC coating material, so that the LTHC coating material is decomposed, releasing reconstructed wafer 100 from carrier 20.

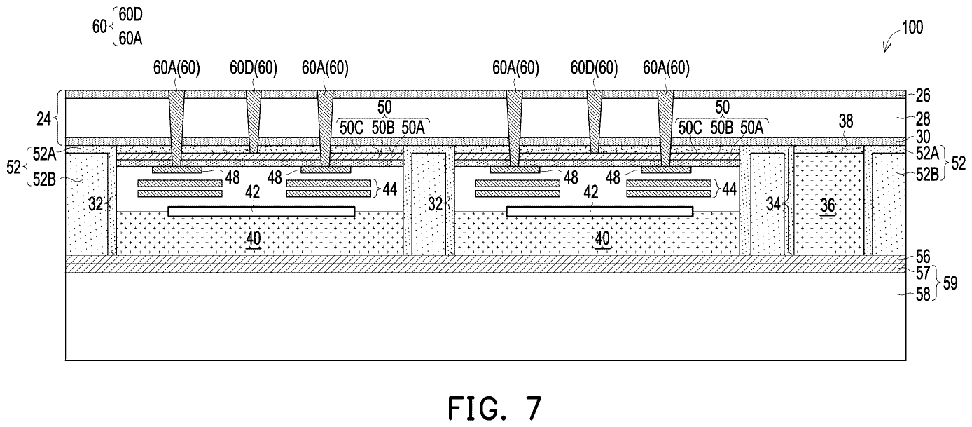

FIG. 7 illustrates the formation of active through-vias 60A and dummy through-vias 60D, which are individually and collectively referred to as through-vias 60. The respective process is illustrated as process 214 in the process flow 200 as shown in FIG. 27. Through-vias 60 may comprise conductive materials such as TiN, TaN, copper, tungsten, cobalt, or the like.

Active through-vias 60A are electrically connected to the metal pads 48 in device dies 32, which are electrically connected to integrated circuit devices 42. In accordance with some embodiments in which dielectric layers 50 cover metal pads 48, active through-vias 60A may penetrate through the dielectric layers 50 to contact the metal pads 48. In accordance with alternative embodiments in which metal pads 48 are formed as the surface features of device dies 32, active through-vias 60A may land on metal pads 48, without penetrating through the dielectric layers 52.

Dummy through-vias 60D may also be formed, for example, with the bottom surfaces of dummy through-vias 60D landing on the top surface of any one of dielectric layers 50C, 50B, and 50A. For example, FIG. 7 illustrates that dummy through-vias 60D land on the top surface of dielectric layer 50B as an example. In accordance with alternative embodiments, dummy metal pads (not shown), which are electrically floating, may be formed under dielectric layers 50 or inside one of dielectric layers 50, and dummy through-vias 60D may land on the dummy metal pads. The dummy metal pads (when formed), may be at a same level as metal pads 48. The bottom ends of active through-vias 60A and dummy through-vias 60D may be at the same level or different levels.

In accordance with some embodiments, the formation of through-vias 60 may include etching-through base bond structure 24 and dielectric layers 50 to form first contact openings for active through-vias 60A, and second contact openings for dummy through-vias 60D. The formation of the first contact openings and the second contact openings may share some common etching processes or may be fully separated etching processes. The filling of the first and the second contact openings may share a common deposition (such as physical vapor deposition) process, plating process, or the like. A planarization process such as a CMP process may be used to planarize the top surface of bond base structure 24 with the top surfaces of through-vias 60.

Since through-vias 60 that electrically conduct signals/voltages through base bond structure 24 are formed after the bonding of device dies 32 to base bond structure 24, the process as shown in FIGS. 1 through 11 is referred to as a routing-last process.

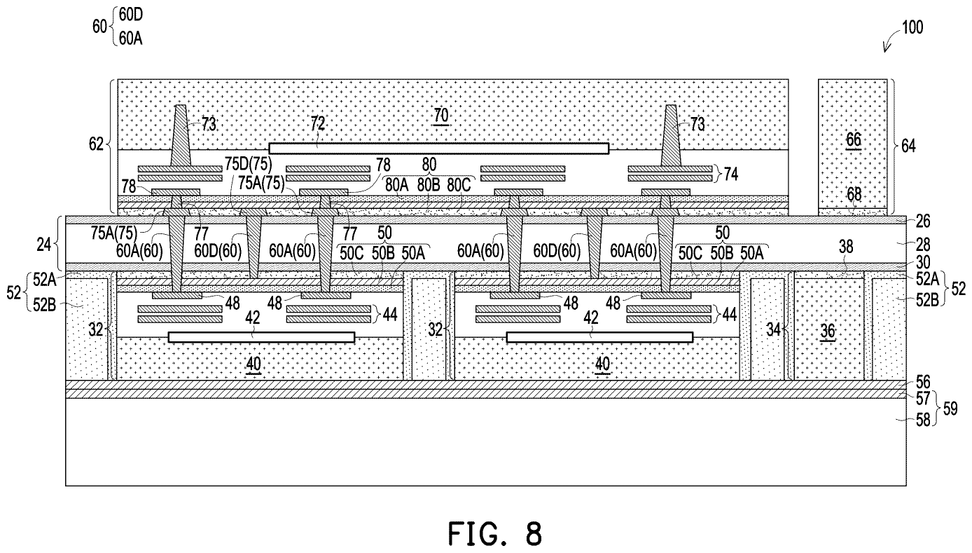

FIGS. 8 through 11 illustrate the formation of additional features to expand reconstructed wafer 100. FIG. 8 illustrates the bonding of device dies 62 to base bond structure 24. The respective process is illustrated as process 216 in the process flow 200 as shown in FIG. 27. Device dies 62 are bonded to the opposite side of base bond structure 24 than device dies 32.

Referring to FIG. 8, although one device die 62 is illustrated, the illustrate device dies 62 represents a plurality of groups device dies 62, with each group being in one of the final package 100′ as shown in FIG. 11. In accordance with some embodiments, each of device dies 62 may be a logic die, an input-output (IO) die, a memory die, or the like. In accordance with some embodiments, as shown in FIG. 8, device dies 62 and device dies 32 are arranged as a face-to-face pattern. In accordance with alternative embodiments, device dies 62 and device dies 32 are arranged as a face-to-back, a back-to-face, or a back-to-back pattern.

Device dies 62 may include semiconductor substrates 70, integrated circuit devices 72, interconnect structures 74, metal pads 78, and dielectric layers 80. Semiconductor substrates 70 may be silicon substrates. Integrated circuit devices 72 may comprise active devices (such as transistors, diodes, and/or the like) and passive devices (such as capacitors, resistors, and/or the like). Interconnect structures 74 are used for connecting to the active devices and passive devices in device dies 62. Interconnect structures 74 include metal lines and vias, as schematically illustrated. The details of device dies 62 may be similar to (or the same as) the corresponding features in device dies 32, and hence may not be repeated herein.

Dielectric layers 80 may include dielectric layers 80A, 80B, and 80C, which are formed of different martials. In accordance with some embodiments, dielectric layer 80C, which is bonded to base bond structure 24, may be an enhanced bond layer (for example, formed of a metal oxide such as Al₂O₃), or may be a silicon-containing dielectric layer comprising SiO, SiN, SiC, SiON, SiCN, SiOCN, or the like. The details of the structure, the layers, and materials of dielectric layers 80 may be the same as, and may be found referring to the discussion of, the dielectric layers 50, and are not repeated herein.

Device dies 62 may include through-vias 73, which extend into semiconductor substrates 70. In accordance with some embodiments, through-vias 73 are electrical connected to integrated circuit devices 72 through interconnect structure 74. Through-vias 73 may also be electrical connected to device dies 32 through active through-vias 60A.

In accordance with some embodiments, bond pads 75 (including active bond pads 75A and dummy bond pads 75D) are formed in dielectric layer 80C. Bond pad vias 77 may be formed in dielectric layers 80A and 80B, and electrically connect active bond pads 75A to integrated circuit devices 72 and through-vias 73. The bonding of device dies 62 to base bond structure 24 may include a hybrid bonding process, in which dielectric layers 80C of device dies 62 are bonded to dielectric layer 30, and bond pads 75 bonded to through-vias 60.

Active bond pads 75A and dummy bond pads 75D are bonded to active through-vias 60A and dummy through-vias 60D, respectively. Dummy bond pads 75D and dummy through-vias 60D may be electrically floating. A combined feature comprising a dummy bond pad 75D and a dummy through-via 60D may be fully enclosed in dielectric materials.

In accordance with some embodiments, a plurality of dummy dies 64 are attached to base bond structure 24. A dummy die 64 may include dummy region 66 (which may comprise silicon) and bond layer 68. The candidate structures and candidate materials of dummy die 64 may be essentially the same as that of dummy die 34, and are not repeated herein.

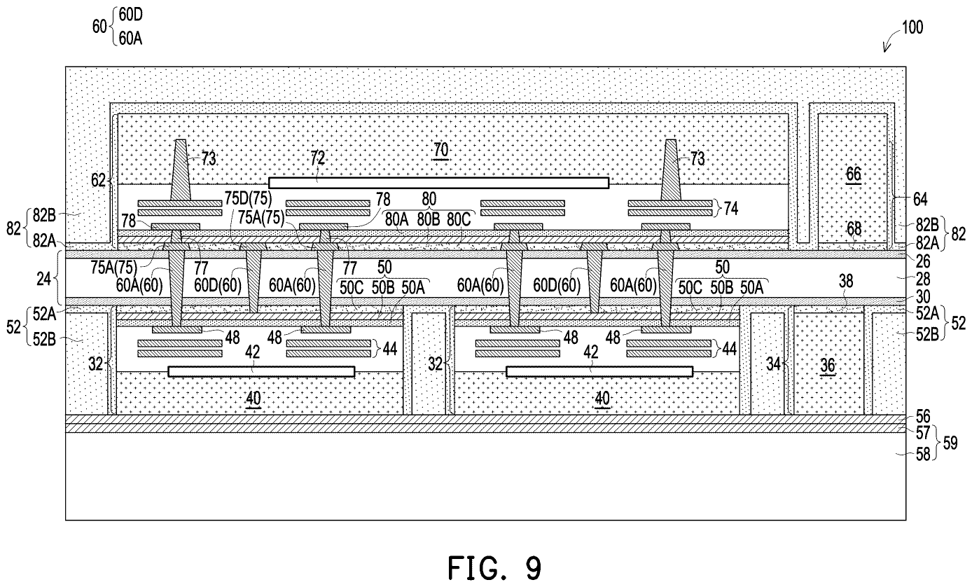

FIG. 9 illustrates the formation of gap-fill layers 82 including adhesion layer 82A and dielectric layer 82B, which are individually and collectively referred to as dielectric layers 82. The respective process is illustrated as process 218 in the process flow 200 as shown in FIG. 27. The candidate structures and candidate materials of gap-fill layers 82 may be essentially the same as that of dielectric layers 52, and are not repeated herein.

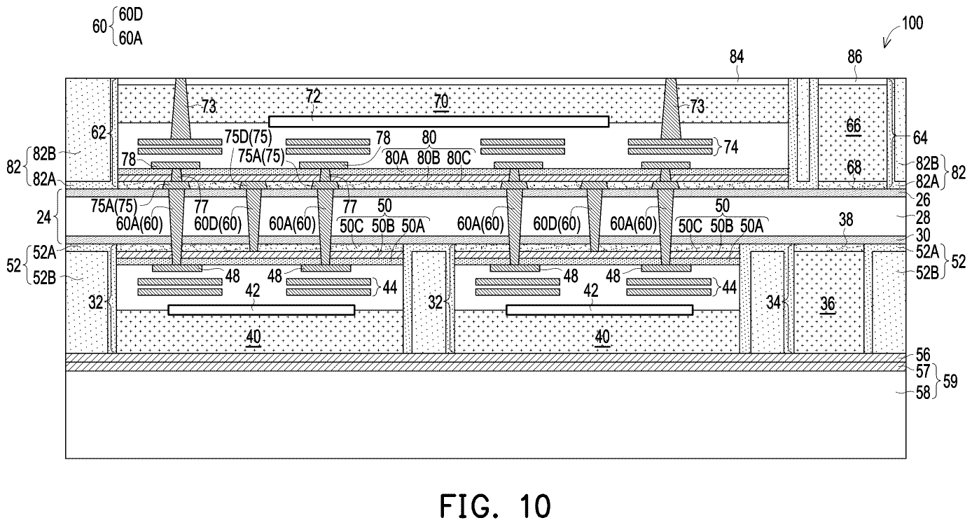

Referring to FIG. 10, a planarization process such as a CMP process or a mechanical grinding process is performed to remove excess portions of dielectric layers 82A and 82B, so that device dies 62 and dummy dies 64 are exposed. The respective process is illustrated as process 220 in the process flow 200 as shown in FIG. 27. The remaining portions of dielectric layers 82A and 82B are individually and collectively referred to as gap-fill regions 82 or dielectric regions 82 hereinafter. Reconstructed wafer 100 is thus expanded to include device dies 62, dummy dies 64, and gap-fill regions 82.

In accordance with some embodiments, after the planarization process, a dummy die 64 is exposed. In accordance with alternative embodiments, after the planarization process, a dummy die 64 is buried in gap-fill regions 82, and a portion of dielectric layer 82A and a portion of dielectric layer 82B may be left overlapping the dummy die 64.

The planarization process may be stopped after through-vias 73 in device dies 62 are exposed. After the planarization process, an etching process may be performed to recess semiconductor substrates 70 and dummy regions 66. Through-vias 73 thus have top portions protruding higher than the top surfaces of the recessed semiconductor substrates 70. The recesses are then filled with a dielectric material such as silicon oxide, silicon nitride, silicon carbide, or the like, followed by a planarization process to remove the portions of the dielectric material outside of the recesses. The remaining portions of the dielectric material are isolation layers 84, which overly the semiconductor substrates 70.

In accordance with some embodiments, for example, when dummy regions 66 comprise a material similar to or the same as the material of semiconductor substrates 70, dummy regions 66 may also be recessed. The remaining portions of the dielectric layer also includes some portion overlapping and contacting dummy regions 66 to form dielectric isolation layers 86.

In a subsequent process, as shown in in FIG. 11, redistribution structure 88 is formed. The respective process is illustrated as process 222 in the process flow 200 as shown in FIG. 27. In accordance with some embodiments, redistribution structure 88 includes dielectric layers 90, and RDLs 92 in dielectric layers 90. Electrical connectors 94 are then formed. Electrical connectors 94 may comprise solder regions, metal pillars, and/or the like. The respective process is illustrated as process 224 in the process flow 200 as shown in FIG. 27. Reconstructed wafer 100 is thus formed.

In subsequent processes, as also shown in FIG. 11, reconstructed wafer 100 is sawed (singulated) in a sawing process, so that identical discrete packages 100′ are formed. The respective process is illustrated as process 226 in the process flow 200 as shown in FIG. 27. The discrete packages 100′ include device dies 32 and 62, and also include dummy dies 34 and 64 and pieces of supporting substrate 59. Packages 100′ may then be bonded to additional package component (not illustrated) such as interposer, package substrates, or the like through electrical connectors 94.

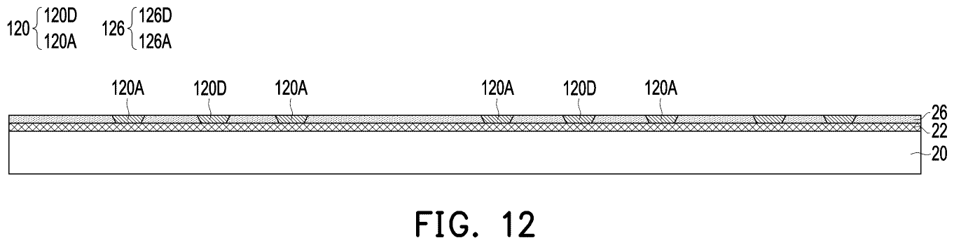

FIGS. 12 through 21 illustrate the cross-sectional views of intermediate stages in the formation of a package in accordance with alternative embodiments of the present disclosure. These embodiments are similar to the embodiments in FIGS. 1 through 11, except that the base bond structure 24 is formed in an RDL-first process, in which redistribution lines are formed in base bond structure 24 before bonding device dies thereon. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

Referring to FIG. 12, carrier 20 is provided, and release film 22 is formed thereon. Dielectric layer 26, which may be (or may not be) an enhanced bond layer, is formed over release film 22, for example, through a deposition process.

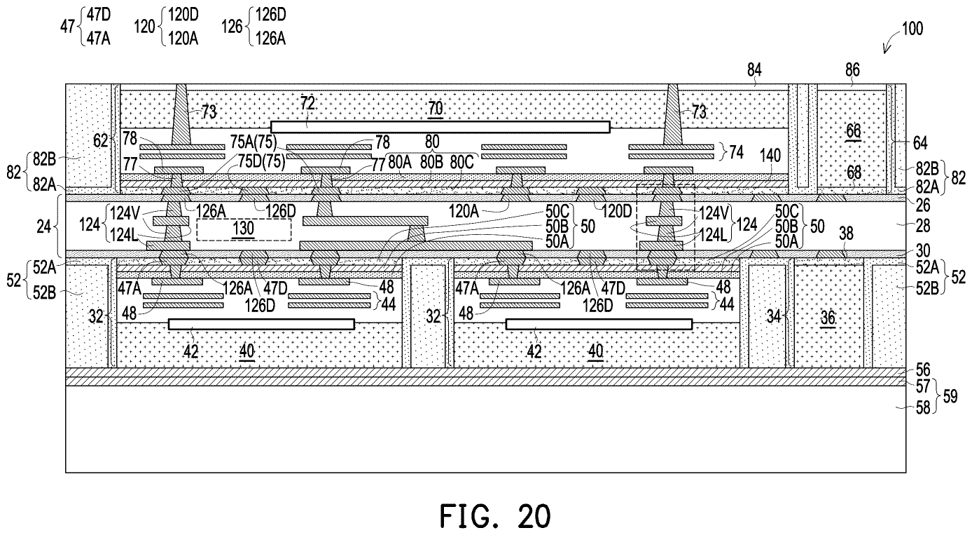

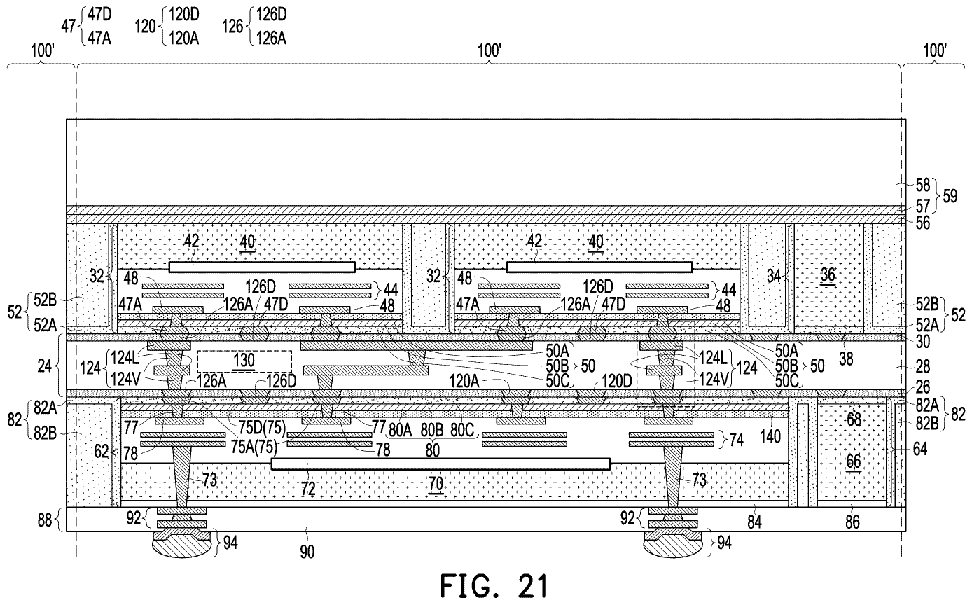

Next, bond pads 120 are formed in dielectric layer 26. In accordance with some embodiments, bond pads 120 include active bond pads 120A and dummy bond pads 120D. Dummy bond pads 120D may be electrically floating in the final package 100′ (FIG. 21), and may be formed to reduce pattern loading and to improve bond strength. The formation process may include a single damascene process, in which openings are first formed in dielectric layer 26, followed by filing the openings with conductive materials such as copper, and a subsequent planarization process to remove excess portions of the conductive material.

Bond pads 120 may be tapered, with the bottom portions being narrower than the respective upper portions. Each of bond pads 120 may (or may not) include a barrier layer (not shown), which may be deposited before the deposition of the conductive materials. The barrier layer may have a U-shape in the cross-sectional view, and the U-shape has an opening facing up.

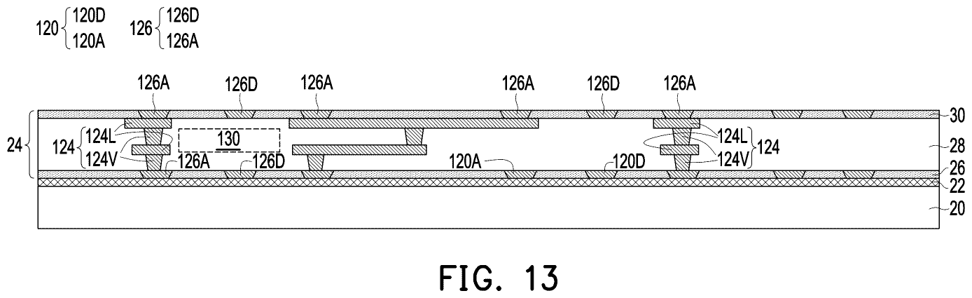

Referring to in FIG. 13, redistribution lines 124, which may include vias 124V and metal lines 124L, are then formed layer-by-layer, and electrically connected to active bond pads 120A. the formation process may include single damascene processes and/or dual damascene processes. The resulting vias 124V may be tapered, with the bottom portions being narrower than the respective upper portions. The resulting redistribution lines 124 may have the structures as shown in FIGS. 23 and/or 24. Redistribution lines 124 are formed in dielectric layers 28. The material of dielectric layer 28 may include SiO, SiN, SiC, SiOCN, SiCN, SiON, or the like, or combinations thereof.

Dielectric layer 30 and bond pads 126 are then formed. Dielectric layer 30 may be, or may not be, an enhanced bond layer. The formation process of bond pads 126 may include a single damascene process. Each of bond pads 126 may (or may not) include a barrier layer (not shown), which may be deposited first, followed by a plating process. The barrier layer may have a U-shape in the cross-sectional view, and the U-shape has an opening facing up.

Bond pads 126 may be tapered, with the bottom portions narrower than the respective upper portions. In accordance with some embodiments, bond pads 126 include active bond pads 126A, and dummy bond pads 126D. Dummy bond pads 126D may be electrically floating in the final structure, and may be formed to reduce pattern loading and to improve bond strength.

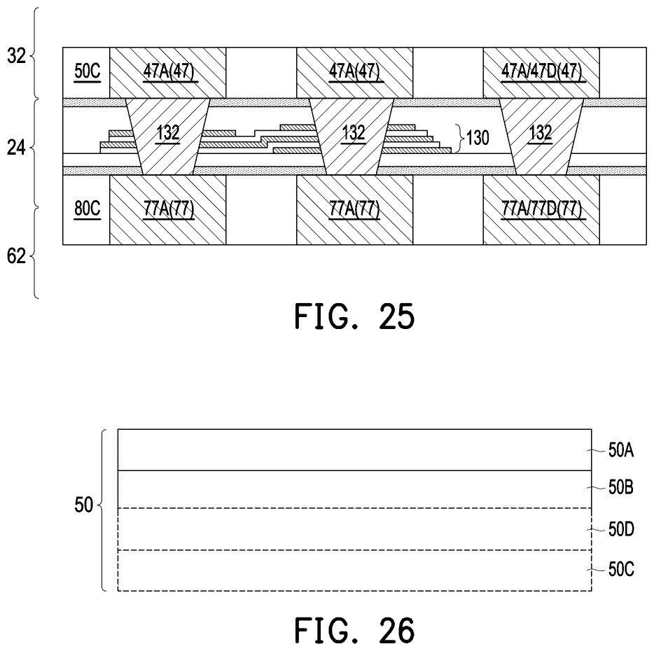

In accordance with some embodiments, capacitor 130 may be formed in dielectric layers 28. The detailed structure of an example capacitor 130 is illustrated in FIG. 25. In accordance with some embodiments, as shown in FIG. 25, capacitor 130 is a metal-insulator-metal (MIM) capacitor, which includes a plurality of metal capacitor plates and a plurality of dielectric insulators between the plurality of metal capacitor plates. The dielectric insulators may be high-k dielectric layers.

Through-vias 132 may be formed to penetrate through the resulting base bond structure 24. The through-vias 132 may be formed after the formation of rest parts of the base bond structure 24. The through-vias 132 are electrically connected to the capacitor plates, so that the capacitor 130 is electrically connected to either one or both of device dies 32 and 62.

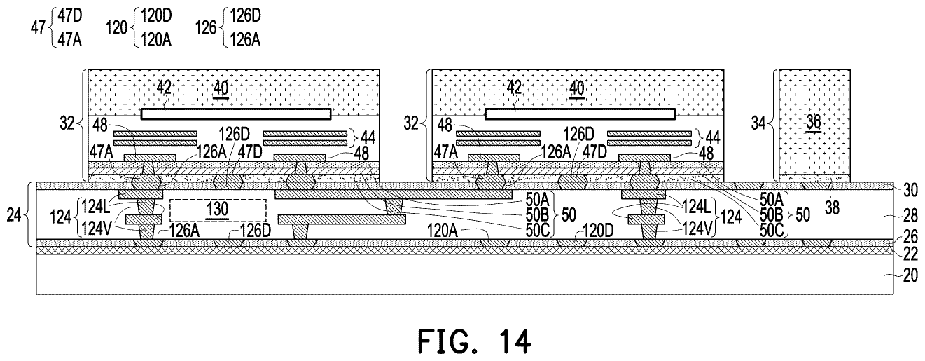

FIG. 14 illustrates the bonding of device dies 32 and the attachment of dummy dies 34 to base bond structure 24. The device dies 32 and dummy dies 34 are essentially the same as discussed referring to the preceding embodiments, and the details may not be repeated. The bonding may be achieved through hybrid bonding, wherein bond pads 47 in device dies 32 are bonded to the bond pads 126 in base bond structure 24, and surface dielectric layers 52C of device dies 32 are bonded to the surface dielectric layer 30 in base bond structure 24.

Device dies 32 further includes bond pads 47 in dielectric layer 50C, and bond pad vias 49 in dielectric layers 50B and 50A. Bond pads 47 may include active bond pads 47A and dummy bond pads 47D. Bond pad vias 49 electrically connect active bond pads 47A to the integrated circuit devices 42. Dummy bond pads 47D are bonded to dummy bond pads 126D, and may be electrically floating in the resulting final package 100′ (FIG. 21).

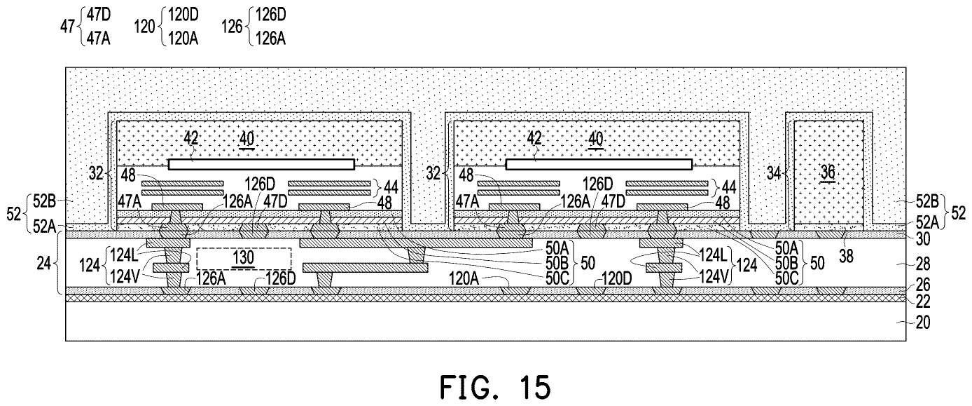

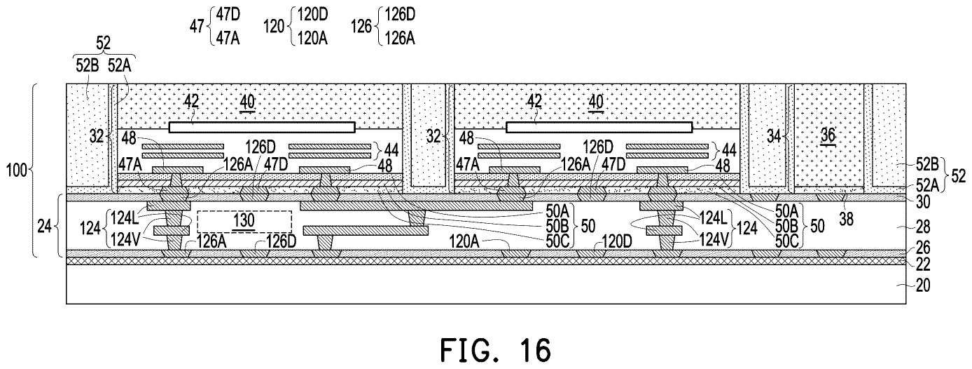

FIG. 15 illustrates the formation of adhesion layer 52A and dielectric layer 52B. Next, as shown in FIG. 16, a planarization process is performed to remove excess portions of adhesion layer 52A and dielectric layer 52B, so that gap-fill regions 52 are formed. The initial structure of reconstructed wafer 100 is thus formed, and reconstructed wafer 100 is further expanded in subsequent steps.

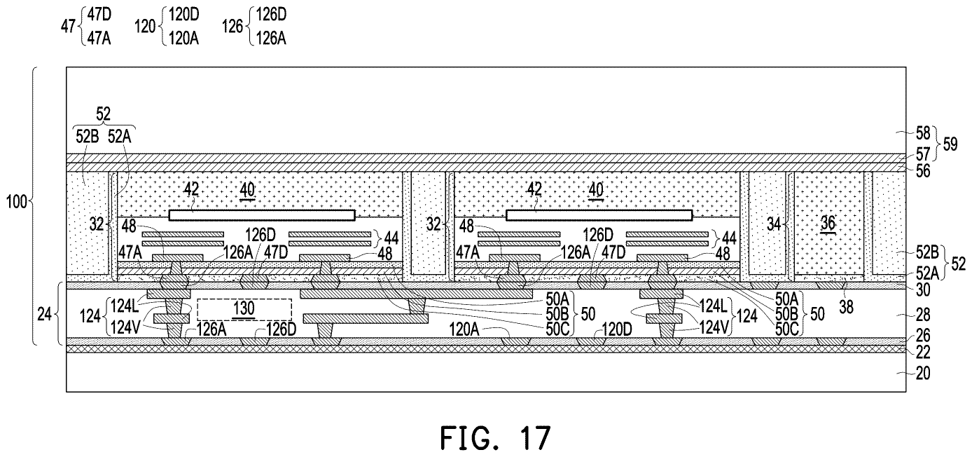

FIG. 17 illustrates the formation of bond layer 56, and the bonding of supporting substrate 59 to bond layer 56. Next, a carrier de-bonding process is performed, so that base bond structure 24 is exposed. The resulting structure is shown in FIG. 18, in which reconstructed wafer 100 is illustrated upside-down.

Next, device dies 62 and dummy dies 64 are bonded/attached to base bond structure 24. The device dies 62 and dummy dies 64 are essentially the same as discussed referring to the preceding embodiments, and the details may not be repeated. The bonding of device dies 62 to base bond structure 24 may be achieved through hybrid bonding, wherein bond pads 75 in device dies 62 are bonded to the bond pads 120 in base bond structure 24, and surface dielectric layers 80C of device dies 62 are bonded to the surface dielectric layer 26 in base bond structure 24. The bonding of dummy dies 64 to base bond structure 24 may be achieved through fusion bonding.

Device dies 62 further includes semiconductor substrates 70, integrated circuits 72, interconnect structures 74, metal pads 78, bond pad vias 77, through-vias 73 and dielectric layers 80. Dielectric layers 80 may include dielectric layers 80A, 80B, and 80C.

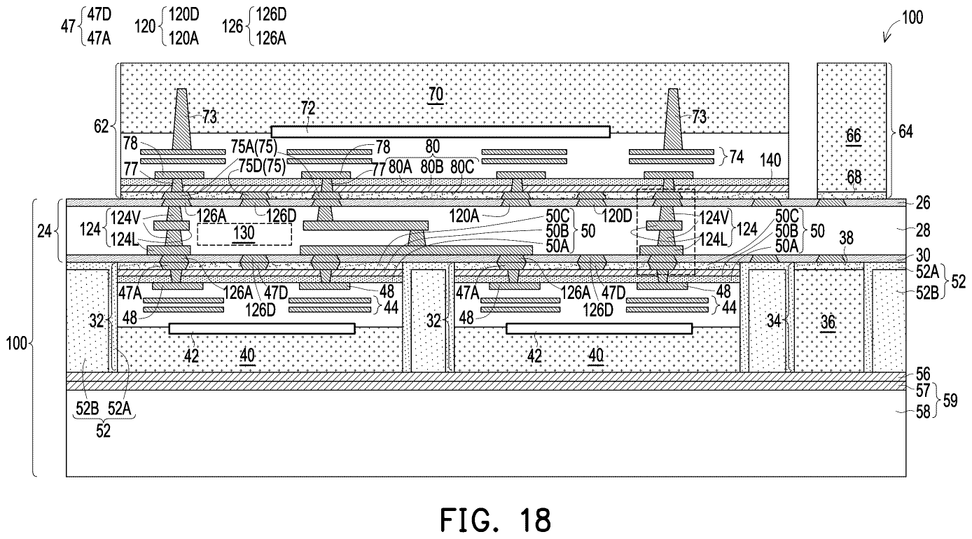

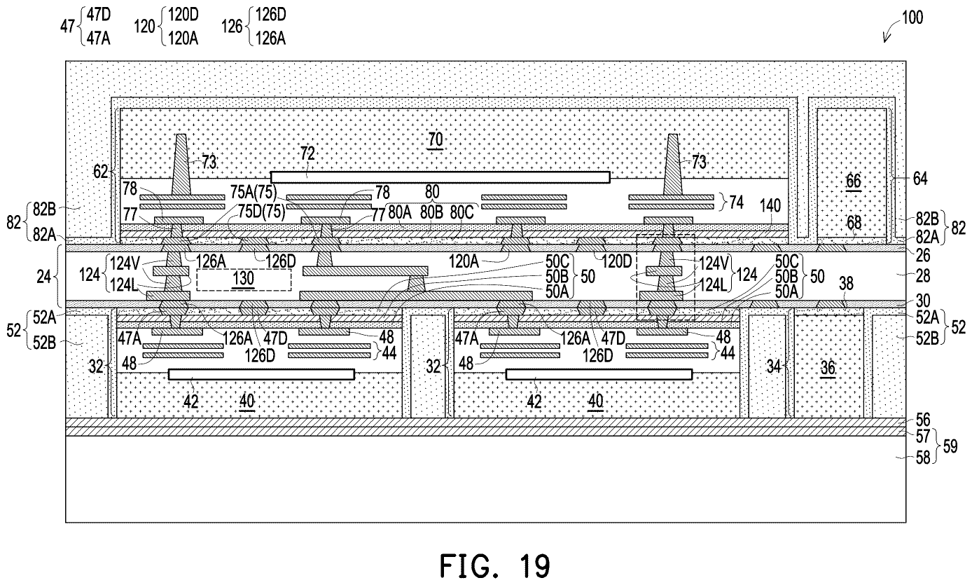

FIG. 19 illustrates the formation of gap-fill layers 82, which include adhesion layer 82A and dielectric layer 82B. Next, as shown in FIG. 20, a planarization process is performed to remove excess portion of adhesion layer 82A and dielectric layer 82B, so that gap-fill regions 82 are formed. Dielectric isolation layers 84 and 86 may then be formed.

FIG. 21 illustrates the formation of redistribution structure 88, which includes dielectric layers 90, RDLs 92, and electrical connectors 94. Reconstructed wafer 100 is thus formed. A sawing process is then performed to saw reconstructed wafer 100 into discrete packages 100′.

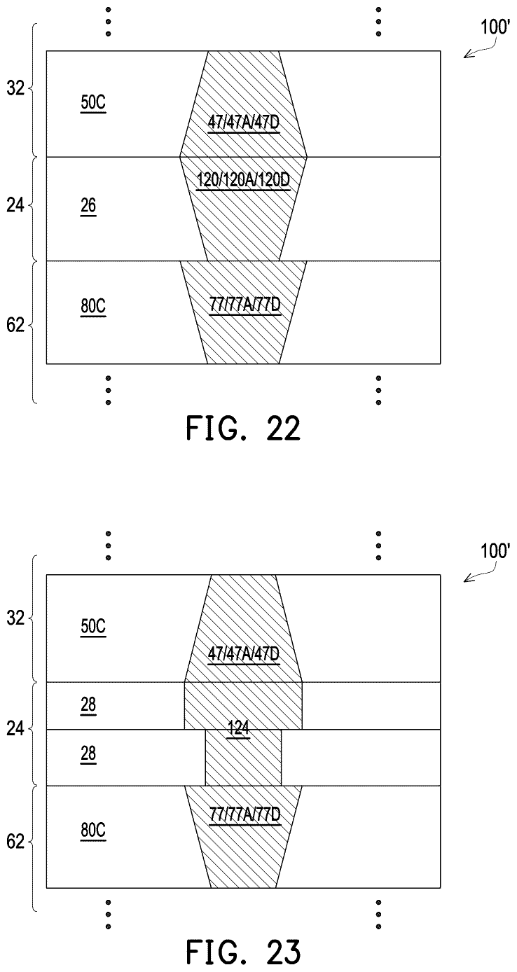

FIG. 22 illustrates a part of package 100′ in accordance with some embodiments. The illustrated part may be in region 140 in FIG. 21, except that in FIG. 21, the redistribution structure in based bond structure 24 includes a plurality of dielectric layers 26, 28, and 30, and a plurality of RDLs 124 in dielectric layer 28. In the embodiments in FIG. 22, on the other hand, the base bond structure 24 includes a single dielectric layer 26, and bond pads 120 (including active bond pads 120A and dummy bond pads 120D) in the dielectric layer 26. The illustrated bond pad 120 may be the active bond pad 120A or dummy bond pad 120D.

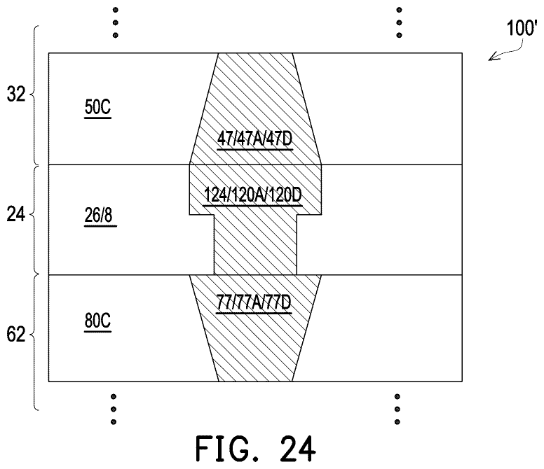

FIG. 23 illustrates an embodiment in which the RDL 124 is formed through two single damascene processes. The base bond structure 24 may also include bond pads over and/or under RDL 124, which bond pads are not illustrated. FIG. 24 illustrates an embodiment in which the RDL 124 is formed through a dual damascene process. The RDL 124 in FIGS. 23 and 24 may represent the structure of a plurality of layers of RDLs when the base bond structure 24 includes a plurality of dielectric layers, or a single layer of RDL when base bond structure 24 is a single-dielectric-layer structure. The base bond structure 24 may also include bond pads over and/or under RDL 124, which bond pads are not illustrated.

The embodiments of the present disclosure have some advantageous features. By forming a base bond structure, and bonding discrete device dies on opposing sides of the base bond structure, it is possible to bond known-good-dies on opposing sides of the base bond structure for forming package. The manufacturing yield is improved over the packages formed through die-to-wafer bonding, in which the defective dies in the wafer will result in defective packages.

In accordance with some embodiments of the present disclosure, a method comprises forming a base bond structure; bonding a first device die to a first side of the base bond structure; encapsulating the first device die in a first gap-fill region; bonding a second device die to a second side of the base bond structure, wherein the first side and the second side are opposing sides of the base bond structure, and wherein after the second device die is bonded, the first device die is electrically coupled to the second device die through a first conductive feature in the base bond structure; encapsulating the second device die in a second gap-fill region; thinning a semiconductor substrate in the second device die to reveal a through-via in the semiconductor substrate; forming a second conductive feature, wherein the second conductive feature is electrically coupled to the first device die through the through-via in the semiconductor substrate of the second device die; and forming an electrical connector to connect to the second conductive feature.

In an embodiment, the first conductive feature is formed through processes comprising after the first device die is bonded to the base bond structure, etching the base bond structure to form an opening; and forming the first conductive feature to fill the opening. In an embodiment, before the first conductive feature is formed, the base bond structure is a dielectric feature, and the base bond structure is free from conductive features therein. In an embodiment, the method further comprises, after the first device die is bonded to the base bond structure, forming a dummy conductive feature penetrating through the base bond structure.

In an embodiment, the dummy conductive feature comprises a portion in the first device die. In an embodiment, at a time the first device die is being bonded to the base bond structure, the base bond structure comprises the first conductive feature therein. In an embodiment, the first conductive feature comprises a redistribution line that comprises a via and a metal line joined to the via. In an embodiment, the method further comprises forming a capacitor in the base bond structure, wherein the capacitor is electrically coupled to both of the first device die and the second device die.

In an embodiment, the base bond structure comprises a first enhanced bond layer, and wherein the first enhanced bond layer is physically joined to the first device die. In an embodiment, the base bond structure further comprises a silicon-containing dielectric layer joining to the first enhanced bond layer, wherein the silicon-containing dielectric layer is configured to have a first bond strength with the first device die, and the first enhanced bond layer is bonded with the first device die with a second bond strength higher than the first bond strength.

In an embodiment, the base bond structure further comprises a second enhanced bond layer physically joined to the second device die, wherein the silicon-containing dielectric layer is between the first enhanced bond layer and the second enhanced bond layer.

In accordance with some embodiments of the present disclosure, a method comprises forming a base bond structure over a carrier; bonding a first device die to a first surface of the base bond structure; encapsulating the first device die in a first gap-fill region; bonding a supporting substrate over the first device die; de-bonding the carrier from the base bond structure to reveal a second surface of the base bond structure; forming an active through-via penetrating through the base bond structure and to electrically couple to the first device die; bonding a second device die to the second surface of the base bond structure, wherein the second device die is bonded to the active through-via; thinning the second device die to reveal a through-silicon via in the second device die; and forming a conductive feature to electrically couple to the first device die through the through-silicon via and the active through-via.

In an embodiment, the active through-via penetrates through a plurality of dielectric layers in the base bond structure to extend into the first device die. In an embodiment, the method further comprises forming a dummy through-via penetrating through the base bond structure, wherein the dummy through-via further extends into the first device die. In an embodiment, the dummy through-via and the active through-via extend into the first device die for different depths. In some embodiments, the first conductive feature is formed through processes comprising after the first device die is bonded to the base bond structure, etching the base bond structure to form an opening; and forming the first conductive feature to fill the opening. In some embodiments, before the first conductive feature is formed, the base bond structure is a dielectric feature, and the base bond structure is free from conductive features therein. In some embodiments, the method further includes after the first device die is bonded to the base bond structure, forming a dummy conductive feature penetrating through the base bond structure. In some embodiments, the dummy conductive feature comprises a portion in the first device die. In some embodiments, at a time the first device die is being bonded to the base bond structure, the base bond structure comprises the first conductive feature therein. In some embodiments, the first conductive feature comprises a redistribution line that comprises a via and a metal line joined to the via. In some embodiments, the method further includes forming a capacitor in the base bond structure, wherein the capacitor is electrically coupled to both of the first device die and the second device die. In some embodiments, the base bond structure comprises a first enhanced bond layer, and wherein the first enhanced bond layer is physically joined to the first device die. In some embodiments, the base bond structure further comprises: a silicon-containing dielectric layer joining to the first enhanced bond layer, wherein the silicon-containing dielectric layer is configured to have a first bond strength with the first device die, and the first enhanced bond layer is bonded with the first device die with a second bond strength higher than the first bond strength. In some embodiments, the base bond structure further comprises a second enhanced bond layer physically joined to the second device die, wherein the silicon-containing dielectric layer is between the first enhanced bond layer and the second enhanced bond layer.

In an embodiment, at a time before the active through-via is formed, an entirety of the base bond structure comprises dielectric materials. In an embodiment, at the time before the active through-via is formed, the base bond structure comprises a plurality of dielectric layers formed of different dielectric materials, and wherein the base bond structure is free from conductive features therein.

In accordance with some embodiments of the present disclosure, a structure comprises a first device die; first gap-fill regions on opposing sides of the first device die; a base bond structure over the first device die and the first gap-fill regions; an active through-via penetrating through the base bond structure to electrically connect to the first device die, wherein the active through-via comprises a straight edge that extends from a bottom surface to a top surface of the base bond structure; a second device die over and joined to the active through-via; second gap-fill regions on opposing sides of the second device die; and a supporting substrate over and joined to the second device die. In some embodiments, the active through-via penetrates through a plurality of dielectric layers in the base bond structure to extend into the first device die. In some embodiments, the method further includes forming a dummy through-via penetrating through the base bond structure, wherein the dummy through-via further extends into the first device die. In some embodiments, the dummy through-via and the active through-via extend into the first device die in different depths. In some embodiments, at a time before the active through-via is formed, an entirety of the base bond structure comprises dielectric materials. In some embodiments, at the time before the active through-via is formed, the base bond structure comprises a plurality of dielectric layers formed of different dielectric materials, and wherein the base bond structure is free from conductive features therein.

In an embodiment, the base bond structure comprises a plurality of dielectric layers, and all conductive features in the base bond structure have additional straight edges extending from the bottom surface to the top surface of the base bond structure. In an embodiment, the straight edge further penetrates through a dielectric layer in the second device die to contact a metal pad in the second device die. In some embodiments, the base bond structure comprises a plurality of dielectric layers, and all conductive features in the base bond structure have additional straight edges extending from the bottom surface to the top surface of the base bond structure. In some embodiments, the straight edge further penetrates through a dielectric layer in the second device die to contact a metal pad in the second device die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a base bond structure;
bonding a first device die to a first side of the base bond structure;
encapsulating the first device die in a first gap-fill region;
bonding a second device die to a second side of the base bond structure,
wherein the first side and the second side are opposing sides of the base bond structure, and wherein after the second device die is bonded, the first device die is electrically coupled to the second device die through a first conductive feature in the base bond structure;
encapsulating the second device die in a second gap-fill region;
thinning a semiconductor substrate in the second device die to reveal a through-via in the semiconductor substrate;
forming a second conductive feature, wherein the second conductive feature is electrically coupled to the first device die through the through-via in the semiconductor substrate of the second device die; and
forming an electrical connector to connect to the second conductive feature.

2. The method of claim 1, wherein the first conductive feature is formed through processes comprising:
after the first device die is bonded to the base bond structure, etching the base bond structure to form an opening; and
forming the first conductive feature to fill the opening.

3. The method of claim 2, wherein before the first conductive feature is formed, the base bond structure is a dielectric feature, and the base bond structure is free from conductive features therein.

4. The method of claim 2 further comprising, after the first device die is bonded to the base bond structure, forming a dummy conductive feature penetrating through the base bond structure.

5. The method of claim 4, wherein the dummy conductive feature comprises a portion in the first device die.

6. The method of claim 1, wherein at a time the first device die is being bonded to the base bond structure, the base bond structure comprises the first conductive feature therein.

7. The method of claim 6, wherein the first conductive feature comprises a redistribution line that comprises a via and a metal line joined to the via.

8. The method of claim 6 further comprising forming a capacitor in the base bond structure, wherein the capacitor is electrically coupled to both of the first device die and the second device die.

9. The method of claim 1, wherein the base bond structure comprises a first enhanced bond layer, and wherein the first enhanced bond layer is physically joined to the first device die.

10. The method of claim 9, wherein the base bond structure further comprises:
a silicon-containing dielectric layer joining to the first enhanced bond layer, wherein the silicon-containing dielectric layer is configured to have a first bond strength with the first device die, and the first enhanced bond layer is bonded with the first device die with a second bond strength higher than the first bond strength.

11. The method of claim 10, wherein the base bond structure further comprises:
a second enhanced bond layer physically joined to the second device die, wherein the silicon-containing dielectric layer is between the first enhanced bond layer and the second enhanced bond layer.

12. A method comprising:
forming a base bond structure over a carrier;
bonding a first device die to a first surface of the base bond structure;
encapsulating the first device die in a first gap-fill region;
bonding a supporting substrate over the first device die;
de-bonding the carrier from the base bond structure to reveal a second surface of the base bond structure;
forming an active through-via penetrating through the base bond structure and to electrically couple to the first device die;
bonding a second device die to the second surface of the base bond structure, wherein the second device die is bonded to the active through-via;
thinning the second device die to reveal a through-silicon via in the second device die; and
forming a conductive feature to electrically couple to the first device die through the through-silicon via and the active through-via.

13. The method of claim 12, wherein the active through-via penetrates through a plurality of dielectric layers in the base bond structure to extend into the first device die.

14. The method of claim 12 further comprising forming a dummy through-via penetrating through the base bond structure, wherein the dummy through-via further extends into the first device die.

15. The method of claim 14, wherein the dummy through-via and the active through-via extend into the first device die in different depths.

16. The method of claim 12, wherein at a time before the active through-via is formed, an entirety of the base bond structure comprises dielectric materials.

17. The method of claim 16, wherein at the time before the active through-via is formed, the base bond structure comprises a plurality of dielectric layers formed of different dielectric materials, and wherein the base bond structure is free from conductive features therein.

18. A structure comprising:
a first device die;
first gap-fill regions on opposing sides of the first device die;
a base bond structure over the first device die and the first gap-fill regions;
an active through-via penetrating through the base bond structure to electrically connect to the first device die, wherein the active through-via comprises a substantially straight edge that extends from a bottom surface to a top surface of the base bond structure;
a second device die over and joined to the active through-via;
second gap-fill regions on opposing sides of the second device die; and
a supporting substrate over the second device die.

19. The structure of claim 18, wherein the base bond structure comprises a plurality of dielectric layers, and all conductive features in the base bond structure have additional straight edges extending from the bottom surface to the top surface of the base bond structure.

20. The structure of claim 18, wherein the straight edge further penetrates through a dielectric layer in the second device die to contact a metal pad in the second device die.
